(19) United States
(12) Patent Application Publication
(10) Pub. No.: US 2008/0019404 A1
(43) Pub. Date: Jan. 24, 2008

(54) Mode Selection and Frequency Tuning of a Laser Cavity

(76) Inventors: Richard H. Abram, Edinburgh (GB); Kyle S. Gardner, Glasgow (GB); Erling Riis, Blanefield (GB)

Correspondence Address: KED & ASSOCIATES, LLP, P.O. Box 221200, Chantilly, VA, 20153-1200, US

(21) Appl. No.: 10/593,777

(22) PCT Filed: Mar. 21, 2005
(86) PCT No.: PCT/GB05/01172

§ 371 Date: Jul. 9, 2007

(30) Foreign Application Priority Data
Mar. 24, 2004 (GB) 0406541.3

(51) Int. Cl. H01S 5/068

(52) U.S. Cl. 372/32

(57) ABSTRACT

A technique for stabilising and scanning a cw-laser cavity (3) is demonstrated. The technique involves the incorporation of an inactivity birefringent etalon (15). Such an etalon provides a means for deriving a polarised electric field component (17) from an intracavity electric field (16) of the laser cavity, the orientation of polarisation of the polarised electric field component being dependent on the frequency and polarisation of the intracavity electric field (16). Appropriate analysis of this polarised electric field component (17) enables the laser cavity to be stabilised and frequency tuned while ensuring single mode operation.

The present invention relates to a method and apparatus for improving the mode selection and frequency tuning of a laser cavity. In particular, the invention relates to the incorporation of an intracavity, anisotropic etalon that provides a means for selecting and stabilising the laser cavity to a single mode operating frequency.

The use of single frequency lasers relies heavily on the ability to select a mode of the laser cavity and maintain it for an extended period of time. This may also include tracking the mode if the length of laser cavity is scanned in order to change the output frequency. This selection is normally carried out with a combination of optical elements inserted into the cavity. These elements may include birefringent filters and etalons.

In the case of widely tuneable lasers the frequency selection requirements placed on these elements are particularly stringent. The first requirement results from the fact that the desired mode of operation is one of a great number of possible modes on which the, cavity may operate. Secondly, the need to tune the laser frequency implies that the selecting element has to be tuned as well, typically by being rotated around one of its axes. As a result, the non-solid mounting techniques normally employed for the selecting element to be rotated makes the laser frequency prone to drifting.

Two main classes of widely tuneable single frequency lasers known to those skilled in the art are Dye lasers and Ti:Sapphire lasers. In both cases the tuning range provided by the gain medium is in excess of 50 THz (or more than 100 nm). The laser cavity modes of which a single one has to be selected are typically spaced by a few hundred MHz. Selection is achieved by insertion within the cavity of a number of optical elements, each of which introduces an operating power loss that is a periodic function of the laser frequency. This period is referred to as the free spectral range (FSR) of the element. Typically, the elements chosen to achieve single frequency operation are selected to have successively smaller free spectral ranges corresponding to successively narrower regions of low insertion loss. As a result only one laser mode is capable of oscillating at a frequency corresponding to a loss minimum of all of the inserted elements. The exact requirements for the mode selecting elements are known to depend on the amount of inhomogeneous to homogeneous broadening in the gain medium as well as any spatial hole burning effects.

In a tuneable single frequency laser coarse wavelength selection is typically achieved through the employment of a birefringent filter within the cavity. This may consist of one or more plates made of a birefringent material and is rotated to select a laser bandwidth of typically less than 200 GHz (0.5 nm). At this point it is often sufficient just to insert a fused silica etalon with a free spectral range of approximately 200 GHz into the cavity to ensure single-mode operation. However, the stability requirements are extremely stringent as the rotation of the etalon by an angle of an order of one thousandth of a degree is sufficient for the laser to jump to the next mode of operation.

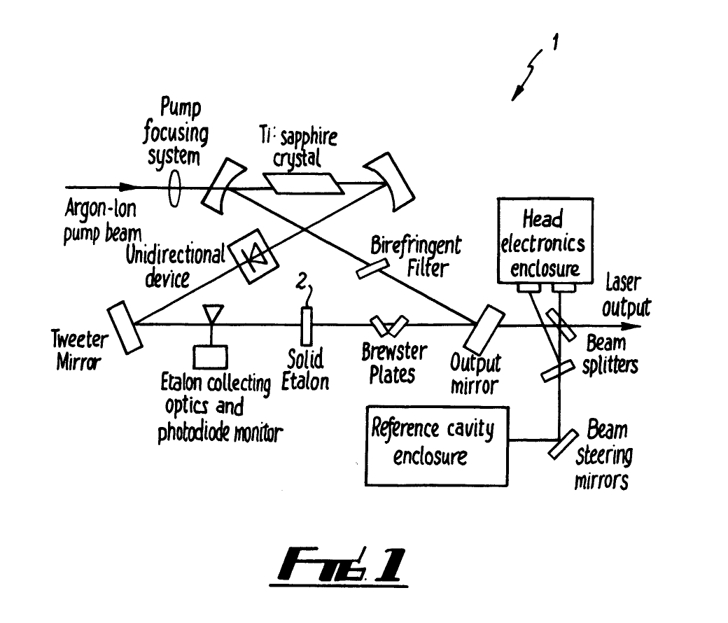

Two main methods have been employed by those skilled in the art in order to prevent the detrimental effect of mode jumping:
1) The first method comprises a passive stabilisation technique that involves the addition of a second etalon, with an even smaller free spectral range, thereby reducing the sensitivity of the first etalon. In the case of a widely tuneable laser an appropriate feed-forward has to be applied to this second etalon in order to track the scanning laser mode. This technique has been successfully implemented within the commercially available Coherent 599/699/899 series of Dye lasers.
2) The second method comprises an active stabilisation technique whereby a feedback is applied to the rotation of a solid etalon so as to keep it locked to the laser mode over long periods of time, and also while the laser is being scanned. This technique is employed within the commercially available Coherent MBR 110 Ti:Sapphire laser 1, see FIG. 1. In particular the electronic signal required for the stabilisation is derived by modulating the angle of the solid etalon 2 at a frequency of 80-90 kHz around a reflection minimum.

Generally, it is appreciated that the fewer intracavity elements included within a laser cavity the simpler the system is to operate, as there are fewer difficulties in relation to the optical alignment of the cavity. Furthermore, the incorporation of additional elements within the laser cavity also acts to reduce the overall output power of the system as each intracavity element introduces an inherent power loss. Therefore, employing the above passive technique has particular disadvantages over that of the described active technique.

Modulating the solid etalon 2 angle so as to derive an. error signal for locking the solid etalon 2 to the cavity in the above active stabilisation technique produces certain inherent detrimental effects on the operation of the laser. In the first instance, the modulated solid etalon 2 introduces a loss in the cavity at twice the modulation frequency, and hence an undesirable intensity modulation results. Secondly, the etalon 2 sets up acoustic vibrations in the cavity, which are then required to be compensated for through the employment of complex electronics.

It is an object of aspects of the present invention to provide a method and apparatus for improving the mode selection and frequency tuning of a laser cavity so as to overcome one or more of the limiting features associated with the methods and apparatus described in the prior art.

According to a first aspect of the present invention there is provided a frequency stabilisation apparatus for stabilising a frequency output of a laser cavity, the frequency stabilisation apparatus comprising an intracavity birefringent etalon, wherein the intracavity birefringent etalon is employed to derive a polarised electric field component from an intracavity electric field of the laser cavity, the orientation of polarisation of the polarised electric field component being dependent on the frequency and polarisation of the intracavity electric field.

Most preferably the intracavity birefringent etalon acts as a first quarter waveplate on the polarised electric field component such that when the frequency of the intracavity electric field corresponds to a resonant frequency of the birefringent etalon the polarised electric field component is linearly polarised.

Preferably the frequency stabilisation apparatus further comprises a second quarter waveplate.

Preferably the frequency stabilisation apparatus further comprises an elliptical polarisation analyser for analysing the state of polarisation of the polarised electric field component on being transmitted through the second quarter waveplate.

Optionally an optical axis of the second quarter waveplate is aligned with an optical axis of the birefringent etalon such that on being transmitted through the second quarter waveplate the polarised electric field component is linearly polarised, the plane of linear polarisation being dependent on the frequency of the intracavity electric field relative to the resonant frequency of the birefringent etalon.

In an alternative arrangement an optical axis of the second quarter waveplate is aligned at 45° relative to an optical axis of the birefringent etalon such that on being transmitted through the second quarter waveplate the polarised electric field component of an off resonance frequency is linearly polarised, the plane of linear polarisation being dependent on the frequency of the intracavity electric field relative to the resonant frequency of the birefringent etalon.

Optionally the elliptical polarisation analyser comprises a polarisation dependent beamsplitter and two light detecting means wherein the polarisation dependent beamsplitter is orientated so as to resolve the polarised electric field component into two spatially separated components each of which is incident on one of the light detecting means.

Preferably the elliptical polarisation analyser further comprises an electronic circuit wherein the electronic circuit derives an error signal from electrical output signals generated by the two light detecting means.

Preferably the electronic circuit further comprises a feedback circuit for generating a feedback signal in response to the error signal so as to control the orientation of the birefringent etalon within the intracavity electric field in order to minimise the magnitude of the error signal.

According to a second aspect of the present invention there is provided frequency scanning apparatus for scanning a frequency output of a laser cavity comprising frequency stabilising apparatus in accordance with a first aspect of the present invention and a cavity length adjuster that provides a means for scanning a length of the laser cavity.

Preferably the cavity length adjuster comprises at least one laser cavity mirror mounted on a piezoelectric crystal.

According to a third aspect of the present invention there is provided a method for stabilising a frequency output of a laser cavity comprising the steps of:
1) Employing a birefringent etalon to sample an intracavity electric field of the laser cavity so as to derive a polarised electric field component whose polarisation is dependent on the polarisation and frequency of the intracavity electric field relative to a resonant frequency of the birefringent etalon;
2) Deriving an error signal from the polarised field component; and
3) Stabilising the birefringent etalon to the derived error signal.

Most preferably the polarised electric field component is linearly polarised when the intracavity electric field corresponds to a resonant frequency of the birefringent etalon.

Preferably the polarised electric field component is elliptically polarised when the intracavity electric field corresponds to a non-resonant frequency of the birefringent etalon. In particular, the helicity of the polarised electric field component is of an alternative sign when the intracavity electric field frequency is above or below the resonant frequency of the birefringent etalon.

Preferably the derivation of the error signal comprises the steps of:
1) Introducing a π/2 phase shift to the orthogonal constituent components of the polarised electric field component;
2) Resolving the orthogonal constituent components of the polarised electric field component; and
3) Calculating an intensity ratio signal the orthogonal constituent components of the polarised electric field component.

Optionally introducing the π/2 phase shift to the orthogonal constituent components of the polarised electric field component results in the plane of polarisation of the polarised electric field component being directly dependent on the frequency of the intracavity electric field relative to the resonant frequency of the birefringent etalon.

Preferably the birefringent etalon is stabilised to the derived error signal by controlling the orientation of the birefringent etalon within the intracavity electric field in order to minimise the magnitude of the error signal

According to a fourth aspect of the present invention there is provided a method for scanning a frequency output of a laser cavity comprising:
1) Stabilising the frequency output of the laser cavity in accordance with a third aspect of the present invention;
2) Scanning an optical length of the laser cavity; and
3) Scanning the orientation of the birefringent etalon within the intracavity electric field in order to track the scanned optical length of the laser cavity.

Aspects and advantages of the present invention will become apparent upon reading the following detailed description and upon reference to the following drawings in which:

FIG. 1 presents a schematic representation of a commercially available Coherent MBR 110 Ti:Sapphire laser that incorporates an active stabilisation technique, as known to those skilled in the art;

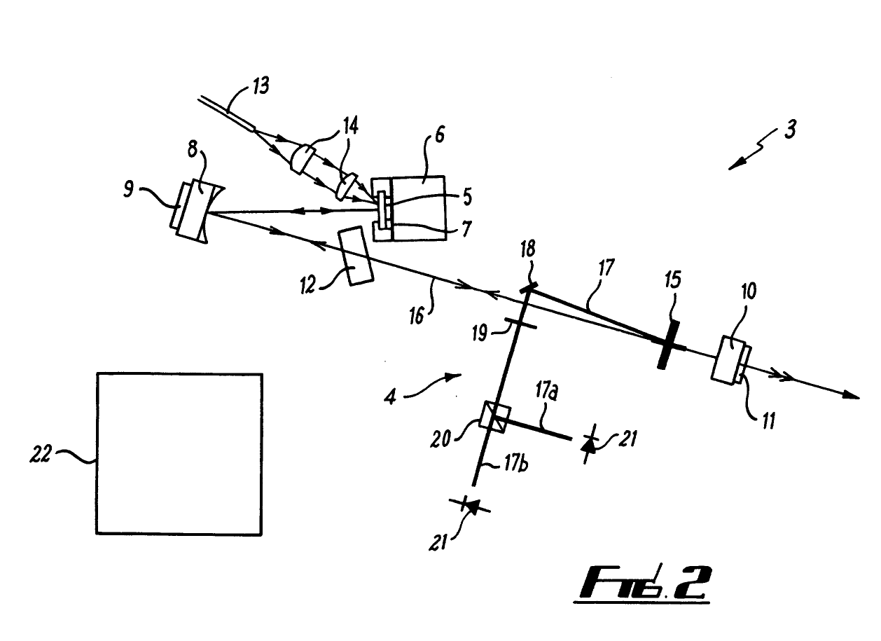

FIG. 2 presents a schematic representation of stabilisation apparatus employed within a vertical external cavity surface emitting laser (VECSEL), in accordance an aspect of the present invention;

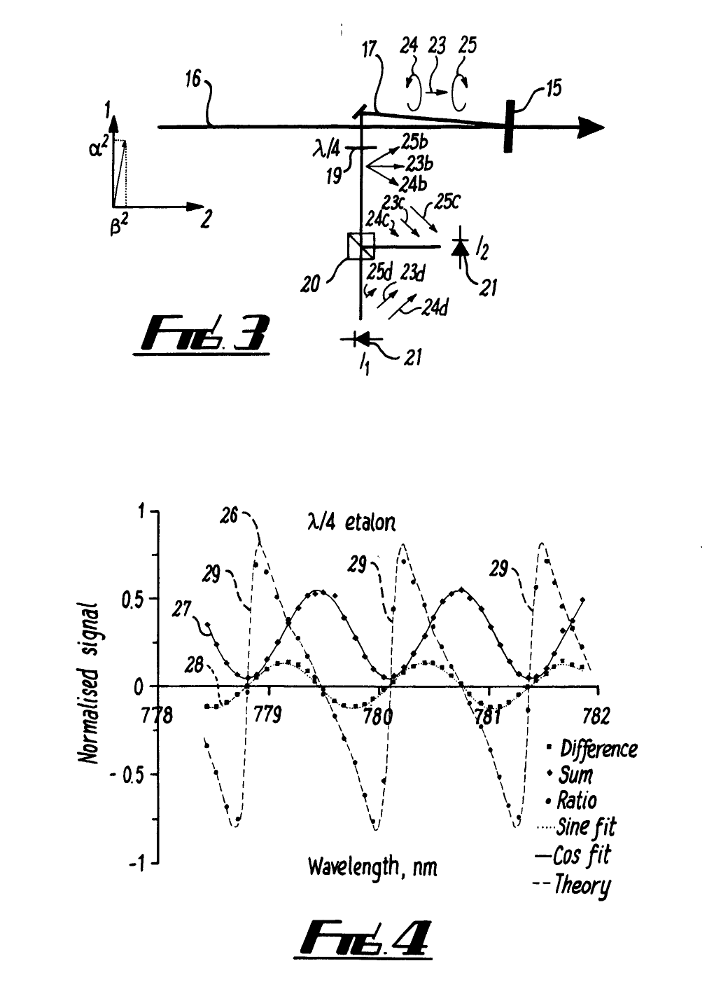

FIG. 3 presents a schematic representation of the principle of operation of the stabilisation apparatus of FIG. 2 when employed within an extra-cavity configuration;

FIG. 4 presents both theoretical and experimental curves relating to a normalised ratio signal as a function of input laser frequency, for the stabilisation apparatus of FIG. 3 when employed with an uncoated birefringent etalon;

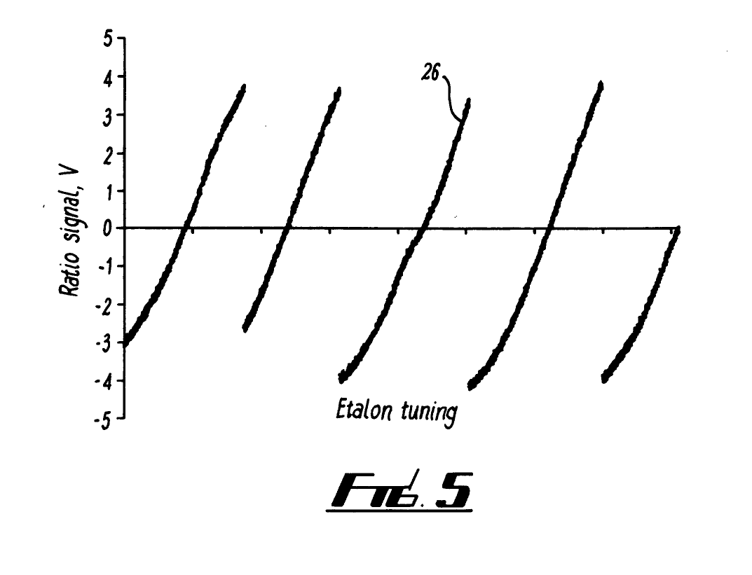

FIG. 5 presents an experimental curve of the normalised ratio signal as a function of birefringent etalon tuning, for the VECSEL 3 of FIG. 2;

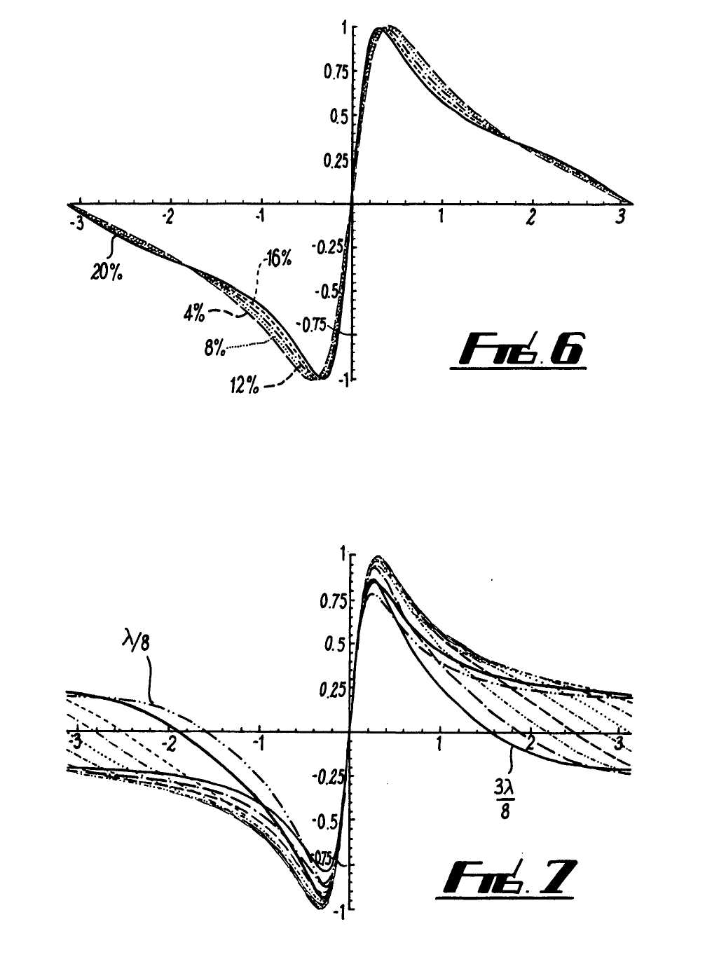

FIG. 6 presents theoretical curves relating to the normalised ratio signal, as a function of input laser frequency, for the stabilisation apparatus of FIG. 3 when employed with a 4%, 8%, 12%, 16% and 20% reflecting birefringent etalon; and

FIG. 7 presents theoretical curves relating to the normalised ratio signal, as a function of input laser frequency, for the stabilisation apparatus of FIG. 3 when employed with a 20% reflecting birefringent etalon and where the retardation of the birefringent etalon varies from a value of λ/8 to 3λ/8.

Referring to FIG. 2 a schematic representation a Vertical External Cavity Surface Emitting Laser (VECSEL) 3 is presented that incorporates stabilisation apparatus 4, in accordance with an aspect of the present invention.

The VECSEL 3 can be seen to comprise a wafer structure 5 mounted within a cooling apparatus 6 that is located within a three mirror folded cavity arrangement. The wafer structure comprises a gain medium (not explicitly shown) made up of twelve 6 nm thick In_{0.16}GaAs quantum wells equally spaced between half-wave Al_{0.06}Ga_{0.8}As/GaAsP structures that allow the VECSEL 3 to be optically pumped at 808 nm, while generating an output in the range of 970-995 nm.

A first mirror within the cavity arrangement comprises an AlAs-GaAs quarter-wave layered Bragg reflector 7 that exhibits a total reflectivity greater than 99.9% centred at 980 nm. A second mirror comprises a standard curved cavity mirror 8 mounted on a first piezoelectric crystal 9, so allowing for fine adjustment of the length of the cavity. An output coupler 10, mounted on a second piezoelectric crystal 11, which allows for coarse adjustment of the length of the cavity, is then employed as the third cavity mirror. Between the curved cavity mirror 8 and the output coupler 10 is located a birefringent filter 12 employed to provide coarse frequency selection within the cavity.

The wafer structure 5 is optically pumped by initially coupling the output of a pump laser source (not shown) into an optical fibre 13. Thereafter, the coupled pump laser output is focussed via two input lens elements 14 onto the wafer structure 5.

The stabilisation apparatus 4 can be seen to comprise a birefringent etalon 15 inserted with a slight angle between one of its axes and an intracavity electric field 16 of the VECSEL 3. The birefringent etalon 15 is coated to act as a 25% reflecting etalon and so directs a reflected component 17 of the incident intracavity electric field 16 towards a beam steering mirror 18 that in turn reflects the field to a quarter waveplate (λ/4 waveplate) 19 and then onto an elliptical polarisation analyser. The first component of the polarisation analyser is a polarisation dependent beamsplitter 20 that divides the reflected electric field 17 into two components 17a and 17b each of which is then incident on a photodiode 21. An electrical circuit 22 is then employed to monitor the signals detected by the photodiode (as described in detail below).

The reflection coefficient Aᵣ(δ, R) for the reflected electric field 17 from the birefringent etalon 15 is given by the expression:

$${A}_{r} ( δ , R ) = \sqrt{R} \frac{1 - exp ( ⅈ δ )}{1 - R exp ( ⅈ δ )} \qquad ( 1 )$$

where R is the intensity reflection coefficient and δ=4π d n cos(θ)/λ is the phase retardation for a roundtrip of the light of wavelength λ in the birefringent etalon 15 which has a thickness d and a refractive index n, and which is tilted at an angle θ to the incident beam. This reflection represents a periodic loss with a period (FSR) of c/(2 n d cos(θ)).

Since the stabilisation apparatus employs a birefringent etalon 15 there are two refractive indices n₁ and n₂ corresponding to the two axes of the material. Hence there are two different values δ₁ and δ₂ for the phase delay. In general this corresponds to different reflectivities for the two polarisations. By designing the birefringent etalon 15 so that the difference δ₁−δ₂ is π modulo 2π, one polarisation of the reflected electric field 17 experiences a reflection maximum when the other has a minimum. This is equivalent to the etalon acting as a λ/4 waveplate for the incident electric field 16.

The ability to stabilise and tune the VECSEL 3 is achieved by inserting the birefringent etalon 15 in the laser cavity in such a way that the direction of polarisation forms a slight angle with one of the optic axes.

To initially demonstrate this effect we first consider the stabilisation apparatus 4 when deployed within an extra-cavity configuration, see FIG. 3. This arrangement is adopted for simplicity of explanation since an intracavity arrangement is complicated by the laser jumping between successive cavity modes. The orientation of the polarisation components of the input laser are represented schematically within the insert of FIG. 3. Specifically, the majority of the light (intensity of this component proportional to α²) is polarised along this axis while a component proportional to β² has orthogonal polarisation (α²+β²=1). Thus, the incident electric field 16 can be written in its two components along the axes of the birefringent etalon:
E(t)=(α E₀ exp(iωt),β E₀ exp(iωt)) (2)
where E₀ is the amplitude and ω the frequency. The reflected electric field is then given by the expression:
Eᵣ(t,δ₁,δ₂,R)=(α E₀ A_{f}(δ₁, R)exp(iωt), β E₀ Aᵣ(δ₂, R)exp(iωt)) (3)

The operating frequency of the VECSEL 3, or the tilt angle of the birefringent etalon 12, is chosen such that the α² component is close to a reflection minimum. At exact resonance the reflection of the component along axis 1 vanishes and the reflected light is linearly polarised 23 along axis 2. Away from exact resonance the reflected electric field 17 is elliptically polarised with opposite helicity for frequencies above 24 and below resonance 25, as is expressed mathematically by Equation 3 above.

By inserting the λ/4 waveplate 19, so that its axes are aligned with those of the birefringent etalon 15, the transmitted light now emerges linearly polarised. For the case of exact resonance 23b the polarisation is orientated along axis 2 and changes clockwise 24b and counter-clockwise 25b, respectively, above and below resonance. It should be noted that the relative rotation of the linearly polarised transmitted light by the λ/4 waveplate 19 would be reversed if the fast and slow axis of the birefringent etalon 15 were reversed.

The incorporation of the polarising beamsplitter, which is rotated 45° with respect to the axes of the birefringent etalon 15, provides a means for analysing the linear polarised fields 23b, 24b and 25b. For the case of the on resonance polarised field 23b an equal amount of light, 23c and 23d, is transmitted to both photodiodes 21. However, for the cases where the frequencies are above 24 and below resonance 25 the amount of light transmitted to the photodiodes 21 is asymmetric, the asymmetry being directly dependent on the frequency shift, see components 24c 24d 25c and 25d, respectively. This provides for the production of an ideal signal for stabilising and tuning the VECSEL 3, as is now described in detail.

The signal for stabilising the VECSEL 3 is a normalised ratio signal 26 given by the following expression:

$$S ( {δ}_{1} , {δ}_{2} , R ) = \frac{{I}_{2} ( {δ}_{1} , {δ}_{2} , R ) - {I}_{1} ( {δ}_{1} , {δ}_{2} , R )}{{I}_{2} ( {δ}_{1} , {δ}_{2} , R ) + {I}_{1} ( {δ}_{1} , {δ}_{2} , R )} = \frac{2 α β Im ⌊ {A}_{r} ( {δ}_{1} , R ) {A}_{r}^{*} ( {δ}_{2} , R ) ⌋}{{α}^{2} {\vert {A}_{r} ( {δ}_{1} , R ) \vert}^{2} + {β}^{2} {\vert {A}_{r} ( {δ}_{1} , R ) \vert}^{2}} \qquad ( 4 )$$

For demonstration purposes FIG. 4 presents experimental (doted) and theoretical (solid) curves obtained for the stabilisation apparatus 4 employed within the extra-cavity configuration. In particular, the sum and difference signals, 27 and 28 respectively, as well as the ratio of the difference and sum signals 26 are presented, as a function of laser input wavelength, over three spectral ranges of the birefringent etalon 15. It should be noted that these results were obtained by employing an uncoated birefringent etalon 15.

Further confirmation of this effect can be seen from FIG. 5 which presents an experimental curve of birefringent etalon 15 tuning versus the normalised ratio signal 26, for the VECSEL 3 of FIG. 2, where the stabilisation apparatus 4 is now employed intracavity. In this particular set up the birefringent etalon is coated so as to reflect 25 % of the intracavity electric field 16. As can be seen, as the birefringent etalon is tilted the operating frequency of the VECSEL is tuned. The normalised ratio signal 26 takes the form of a sequence of continuous curves that pass through zero. The discontinuities correspond to mode jumping occurring in the operating frequency of the VECSEL 3.

The ratio signal 26, and in particular the positive gradient sections 29, are ideal for stabilising the birefringent etalon 15 to a minimum reflection point and hence for stabilising the VECSEL 3. This is achieved through the employment of a feedback loop (not shown) of the electrical circuit. In particular, the feedback loop acts to keep the birefringent etalon 15 at the zero crossing points of one of the positive gradient sections 29. This is achieved by time integrating the ratio signal and thereafter transmitting a feedback signal, with the appropriate sign, so as to control the angle of rotation of the birefringent etalon 15, a technique that is known to those skilled in the art.

The electrical circuit 22 is also employed to provide signals to the first 9 and second piezo electric crystals 11, thereby altering the cavity length and so altering the output frequency of the VECSEL 3. The feedback circuit is then employed, in conjunction with a reference signal forwarded from the first piezo electric crystal 9 so as to allow the birefringent etalon 15 to track the controlled movement of the curved cavity mirror 8 and hence track the operating frequency of the VECSEL 3. This provides a means for continuously scanning the operating frequency of a single mode of the VECSEL 3 over a range of ˜40 GHz.

The robust nature and flexibility of the above stabilisation apparatus 4 can be seen from the following considerations of the effect on the ratio signal 26 of various experimental parameters for the extra-cavity configuration employed in FIG. 3. In the first instance, the calculated ratio signal 26 for a range of birefringent etalon 15 reflectivities, namely of 4%, 8%, 12%, 16% and 20%, is shown in FIG. 6. It is apparent that the effect of increasing the reflectivity from 4% (corresponding to uncoated quartz) to 20% only amounts to a slight increase in the slope of the positive gradient sections 29. Therefore, it will be apparent to those skilled in the art that the above described method and apparatus leaves the reflectivity of the birefringent etalon 15 as a free parameter that can be determined by the requirements of mode selection in a particular laser cavity.

As the method and apparatus is employed within a tuneable laser system it is also relevant to consider the effect on the ratio signal 26 of a deviation from an exact quarter-wave retardation of the birefringent etalon 15. Generally speaking waveplates are only exact waveplates for a particular wavelength. The widest bandwidth for an etalon (i.e. the slowest variation of the phase retardation with respect to wavelength) is obtained with a true zero-order plate. Therefore, for the birefringent etalon 15 that is where the difference in optical thickness experienced by light polarised along the two optic axes is exactly a quarter of a wavelength. This generally corresponds to an extremely thin plate (tens of micron), that in practice is found to be too thin for practical use as an etalon. Within the VECSEL 3 a thickness of the order of 0.5 mm is required for the birefringent etalon 15 to perform its full function. As a result a higher-order plate is required to be used within the laser cavity, i.e. one where the optical thickness difference was qλ±/4, where q is an integer.

For a quartz waveplate with an approximate thickness of 0.3 mm the retardation is known to vary by less than ±λ/8 when the laser wavelength is varied by ±20 nm around the design wavelength. FIG. 7 shows theoretical ratio signal for a variation of ±λ/8. As can be seen the ratio signal 26 develops a slight asymmetry, but the zero-crossing remains at the correct point while the gradient at the zero-crossing remains unaffected. This clearly demonstrates that the technique is robust to realistic variations in retardation encountered in experimental realisations of the scheme and shows that the system may be readily incorporated for use within any continues wave laser system that requires to operate single frequency e.g. Dye and Ti:Sapphire systems.

It will be appreciated by those skilled in the art that the stabilisation apparatus 4 will operate in a similar manner if the λ/4 waveplate 19 is arranged so that its axes are aligned at 45° with those of the birefringent etalon 15. For the case of exact resonance 23 the polarisation of the emerging light is circularly polarised. However, as described above off resonance frequencies emerge linearly polarised, their plane of polarisation being rotated clockwise 24b and counter-clockwise 25b, respectively, above and below resonance. It should be again be noted that the relative rotation of the polarised transmitted light by the λ/4 waveplate 19 is reversed if the fast and slow axis of the birefringent etalon 15 are reversed.

The incorporation of the polarising beamsplitter again provides a means for analysing the resonant, circularly polarised field 23 and non resonant, linearly polarised fields 24b and 25b. The on resonance polarised field 23 will again result in equal amount of light, 23c and 23d, being transmitted to both photodiodes 21. However, for the cases where the frequencies are above 24 and below resonance 25 the amount of light transmitted to the photodiodes 21 is again asymmetric, the asymmetry being directly dependent on the frequency shift, see components 24c 24d 25c and 25d, respectively. Thus a signal suitable for stabilising and tuning the VECSEL 3 is again produced.

It will be appreciated by those skilled in the art that alternative relative angles between the λ/4 waveplate 19 and the birefringent etalon 15 will still produce signals suitable for stabilising and tuning the VECSEL 3 however these will be of reduced efficiency to the arrangements described above.

Aspects of the present invention exhibit a number of significant advantages over the stabilisation and laser tuning techniques employed in the prior art. In the first instance the present system employs fewer optical elements that those comprising passive stabilisation systems. This makes the systems simpler to align and maintain while reducing cost. Furthermore, the present system does not require the employment of an etalon modulation technique as used in known active stabilisation systems. This is of major benefit for the operation of the laser as it avoids the inherent losses and acoustic vibrations introduced to the cavity by the modulating etalon. A direct result of the removal of the effects of acoustic vibrations is that the control electronics can then be significantly simplified.

The foregoing description of the invention has been presented for purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated. Therefore, further modifications or improvements may be incorporated without departing from the scope of the invention as defined by the appended claims.

1. A frequency stabilisation apparatus for stabilising a frequency output of a laser cavity, the frequency stabilisation apparatus comprising an intracavity birefringent etalon, wherein the intracavity birefringent etalon is employed to derive a polarised electric field component from an intracavity electric field of the laser cavity, the orientation of polarisation of the polarised electric field component being dependent on the frequency and polarisation of the intracavity electric field.

2. A frequency stabilisation apparatus as claimed in claim 1 wherein the intracavity birefringent etalon acts as a first quarter waveplate on the polarised electric field component such that when the frequency of the intracavity electric field corresponds to a resonant frequency of the birefringent etalon the polarised electric field component is linearly polarised.

3. A frequency stabilisation apparatus as claimed in claim 1 wherein the frequency stabilisation apparatus further comprises a second quarter waveplate.

4. A frequency stabilisation apparatus as claimed in claim 3 wherein the frequency stabilisation apparatus further comprises an elliptical polarisation analyser for analysing the state of polarisation of the polarised electric field component on being transmitted through the second quarter waveplate.

5. A frequency stabilisation apparatus as claimed in claim 4 wherein an optical axis of the second quarter waveplate is aligned with an optical axis of the birefringent etalon such that on being transmitted through the second quarter waveplate the polarised electric field component is linearly polarised, the plane of linear polarisation being dependent on the frequency of the intracavity electric field relative to the resonant frequency of the birefringent etalon.

6. A frequency stabilisation apparatus as claimed in claim 4 wherein an optical axis of the second quarter waveplate is aligned at 45° relative to an optical axis of the birefringent etalon such that on being transmitted through the second quarter waveplate the polarised electric field component of an off resonance frequency is linearly polarised, the plane of linear polarisation being dependent on the frequency of the intracavity electric field relative to the resonant frequency of the bi-refringent etalon.

7. A frequency stabilisation apparatus as claimed in claim 4 wherein the elliptical polarisation analyser comprises a polarisation dependent beamsplitter and two light detecting means wherein the polarisation dependent beamsplitter is orientated so as to resolve the polarised electric field component into two spatially separated components each of which is incident on one of the light detecting means.

8. A frequency stabilisation apparatus as claimed in claim 7 wherein the elliptical polarisation analyser further comprises an electronic circuit wherein the electronic circuit derives an error signal from electrical output signals generated by the two light detecting means.

9. A frequency stabilisation apparatus as claimed in claim 8 wherein the electronic circuit further comprises a feedback circuit for generating a feedback signal in response to the error signal so as to control the orientation of the birefringent etalon within the intracavity electric field in order to minimise the magnitude of the error signal.

10. A frequency scanning apparatus for scanning a frequency output of a laser cavity comprising a frequency stabilising apparatus as claimed in claim 1 and a cavity length adjuster that provides a means for scanning a length of the laser cavity.

11. A frequency scanning apparatus as claimed in claim 10 wherein the cavity length adjuster comprises at least one laser cavity mirror mounted on a piezoelectric crystal.

12. A method for stabilising a frequency output of a laser cavity comprising the steps of:
employing a birefringent etalon to sample an intracavity electric field of the laser cavity so as to derive a polarised electric field component whose polarisation is dependent on the polarisation and frequency of the intracavity electric field relative to a resonant frequency of the birefringent etalon;
deriving an error signal from the polarised field component; and
stabilising the birefringent etalon to the derived error signal.

13. A method as claimed in claim 12 wherein the polarised electric field component is linearly polarised when the intracavity electric field corresponds to a resonant frequency of the birefringent etalon.

14. A method as claimed in claim 12 wherein the polarised electric field component is elliptically polarised when the intracavity electric field corresponds to a non-resonant frequency of the birefringent etalon.

15. A method as claimed in claim 14 wherein the helicity of the polarised electric field component is of an alternative sign when the intracavity electric field frequency is above or below the resonant frequency of the birefringent etalon.

16. A method as claimed in claim 12 wherein the step of deriving the error signal comprises the steps of:
introducing a p/2 phase shift to the orthogonal constituent components of the polarised electric field component;
resolving the orthogonal constituent components of the polarised electric field component; and
calculating an intensity ratio signal the orthogonal constituent components of the polarised electric field component.

17. A method as claimed in claim 16 wherein the step of introducing the p/2 phase shift to the orthogonal constituent components of the polarised electric field component results in the plane of polarisation of the polarised electric field component being directly dependent on the frequency of the intracavity electric field relative to the resonant frequency of the birefringent etalon.

18. A method as claimed in claim 12 wherein the birefringent etalon is stabilised to the derived error signal by controlling the orientation of the birefringent etalon within the intracavity electric field in order to minimise the magnitude of the error signal.

19. A method for scanning a frequency output of a laser cavity comprising:
stabilising the frequency output of the laser cavity in accordance with the method of claim 12;
scanning an optical length of the laser cavity; and
scanning the orientation of the birefringent etalon within the intracavity electric field in order to track the scanned optical length of the laser cavity.
